(19) United States
(12) Patent Application Publication
(10) Pub. No.: US 2007/0035019 A1
(43) Pub. Date: Feb. 15, 2007

(54) Semiconductor component and method of manufacture

(75) Inventors: Francis J. Carney, Queen Creek, AZ (US); Michael J. Seddon, Gilbert, AZ (US)

Correspondence Address: SEMICONDUCTOR COMPONENTS INDUSTRIES, LLC;BRADLEY J. BOTSCH, 5005 E. MCDOWELL ROAD, INTELLECTUAL PROPERTY DEPT. - A700, PHOENIX, AZ, 85008, US

(73) Assignee: Semiconductor Components Industries, LLC.

(21) Appl. No.: 11/202,965

(22) Filed: Aug. 15, 2005

(51) Int. Cl. H01L 23/48

(52) U.S. Cl. 257/734

(57) ABSTRACT

A semiconductor component having a positionally adaptable locking feature and a method for manufacturing the semiconductor component using a wire bond tool. A conductive support substrate having a flag portion, a lead portion and tie-bars is provided. A semiconductor chip is coupled to the flag portion of the conductive support substrate. A conductive attachment structure couples the semiconductor chip to the lead portion. One or more positionally adaptable locking features are formed on the conductive substrate such that they extend upward from the substrate. Alternatively, the positionally adaptable locking features can be formed on the conductive attachment structure, the semiconductor chip, the tie-bars, other circuit elements, or combinations thereof. The positionally adaptable locking features may be bonding wires, wire bond posts, or the like. An encapsulant encapsulates the semiconductor chip, the conductive substrate, the conductive attachment structure, and the positionally adaptable locking features.

### FIELD OF THE INVENTION

The present invention relates, in general, to semiconductor components and, more particularly, to semiconductor component packaging.

### BACKGROUND OF THE INVENTION

Semiconductor component manufacturers are constantly striving to increase the performance of their products while decreasing their cost of manufacture. A cost intensive area in the manufacture of semiconductor components is packaging the semiconductor chips that contain the semiconductor devices. As those skilled in the art are aware, discrete semiconductor devices and integrated circuits are fabricated from semiconductor wafers, which are then singulated or diced to produce semiconductor chips. Typically, one or more semiconductor chips is attached to a support substrate such as a metal leadframe using a solder die attach material and encapsulated within a mold compound to provide protection from environmental and physical stresses.

A drawback with attaching a semiconductor chip to a metal leadframe using a solder die attach material is that the heat generated during subsequent processing steps causes the die attach material to spread or flow out from beneath the semiconductor chip. This can result in the semiconductor chip tilting or rotating from its desired location on the leadframe. Tilting of the semiconductor chip creates regions of stress in localized areas where the die attach material is thin, which can lead to chip cracking. What is more, rotation of a semiconductor chip from its desired position can create alignment problems during wire bond formation.

Another drawback is that mold compounds or encapsulating materials do not adhere well to die attach materials. The increased leadframe surface area occupied by the die attach material leads to delamination of the mold compound from the leadframe which results in cracks in the die attach material, the semiconductor chips, the package, or combinations thereof. One approach to solving the delamination problem has been to mount smaller semiconductor chips to the leadframe, thereby increasing the total surface area of the leadframe available for bonding to the mold compound. However, this approach is an inefficient use of space and increases the cost of the semiconductor components.

Hence, a need exists for a semiconductor component and a method of manufacturing the semiconductor component that improves adhesion of encapsulating material to a support substrate. It would be advantageous for the semiconductor component and the method for manufacturing the semiconductor component to be cost and time efficient to implement in a semiconductor manufacturing process.

### SUMMARY OF THE INVENTION

The present invention satisfies the foregoing need by providing a semiconductor component having mold lock features and a method for manufacturing the semiconductor component. In accordance with one embodiment, the present invention comprises a substrate having first and second major surfaces. A semiconductor chip is coupled to the first major surface of the substrate and at least one positionally adaptable locking feature is coupled to at least one of the substrate or the semiconductor chip, wherein the primary functionality of the at least one positionally adaptable locking feature is to increase the mechanical integrity of the semiconductor component. An encapsulant is coupled to the at least one positionally adaptable locking feature.

In accordance with another embodiment, the present invention includes a semiconductor component comprising a conductive substrate having a surface and a semiconductor chip coupled to the surface. A locationally flexible locking feature is coupled to at least one of the semiconductor chip or the conductive substrate, wherein the primary functionality of the locationally flexible locking feature is to increase the mechanical integrity of the semiconductor component. An encapsulating material is coupled to the locationally flexible locking feature.

In accordance with yet another embodiment, the present invention includes a method for packaging a semiconductor chip comprising providing a support substrate having a major surface and coupling a semiconductor chip to the major surface. A positionally adaptable locking feature is coupled to the support substrate, wherein the primary functionality of the positionally adaptable locking feature is to increase the mechanical integrity of the packaged semiconductor chip. An encapsulant is disposed on the mold lock feature.

### BRIEF DESCRIPTION OF THE DRAWINGS

The present invention will be better understood from a reading of the following detailed description, taken in conjunction with the accompanying drawing figures, in which like reference numbers designate like elements and in which:

FIG. 1 is a top view of a portion of a semiconductor component at an early stage of manufacture in accordance with an embodiment of the present invention;

FIG. 2 is a cross-sectional side view taken along section line 2-2 of the semiconductor component of FIG. 1 at a later stage of manufacture;

FIG. 3 is a cross-sectional side view taken along section line 3-3 of the semiconductor component of FIG. 1 at a later stage of manufacture;

FIG. 4 is a top view of a portion of a semiconductor component at an early stage of manufacture in accordance with another embodiment of the present invention;

FIG. 5 is a cross-sectional side view taken along section line 5-5 of the semiconductor component of FIG. 4 at a later stage of manufacture;

FIG. 6 is a top view of a portion of a semiconductor component at an early stage of manufacture in accordance with yet another embodiment of the present invention;

FIG. 7 is a cross-sectional side view taken along section line 7-7 of the semiconductor component of FIG. 6 at a later stage of manufacture;

FIG. 8 is a top view of a portion of a semiconductor component at an early stage of manufacture in accordance with yet another embodiment of the present invention;

FIG. 9 is a cross-sectional side view taken along section line 9-9 of the semiconductor component of FIG. 8 at a later stage of manufacture;

FIG. 10 is a top view of a portion of a semiconductor component at an early stage of manufacture in accordance with yet another embodiment of the present invention;

FIG. 11 is a top view of a portion of a semiconductor component at an early stage of manufacture in accordance with yet another embodiment of the present invention; and

FIG. 12 is a cross-sectional side view taken along section line 12-12 of the semiconductor component of FIG. 11 at a later stage of manufacture.

### DETAILED DESCRIPTION

Generally, the present invention provides a semiconductor component having one or more features for locking or promoting adhesion of an encapsulating material, also referred to as an encapsulant, to a support substrate and an element mounted to the support substrate. In addition, the semiconductor component may include one or more alignment features to facilitate aligning active or passive circuit elements on a support substrate. The semiconductor component comprises a support substrate such as, for example, a leadframe having a surface with a chip receiving area. A semiconductor chip is mounted to the chip receiving area and an encapsulating material is formed on and extends upward from the support substrate. The encapsulating material covers the semiconductor chip and a portion of the support substrate. Suitable materials for the encapsulating material include mold compound, liquid encapsulants such as, for example, liquid steel, or the like. In accordance with one embodiment, one or more protrusions extend upward from the surface of the support substrate that has the chip receiving area. The protrusions may be bonding wires, bonding wires coupled in a stitch bond configuration, electrically conductive strips coupled in a ribbon bond configuration, or posts formed using a wire bonding tool. Bonding wires are also referred to as wire bonds. The protrusions increase the surface area to which the encapsulant can bond thereby inhibiting delamination of the encapsulant from the support substrate and elements mounted on the support substrate. Thus, the protrusions serve as locking features. Because the positions or locations of the locking features are not fixed, the locking features are referred to as positionally adaptable locking features or locationally flexible locking features. In addition, the locking features can serve as alignment aids for positioning elements such as semiconductor chips, resistors, capacitors, inductors, etc. on the support substrate and to limit or prevent migration or movement of the elements arising from liquefaction of the die attach material during high temperature processing.

It should be noted that the positionally adaptable or locationally flexible locking features do not directly contribute to the electrical functionality or the circuit functionality of the semiconductor component. An advantage of the present invention is that the primary functionality of the at least one positionally adaptable locking feature or the locationally flexible locking feature is that it increases the mechanical integrity of the semiconductor component.

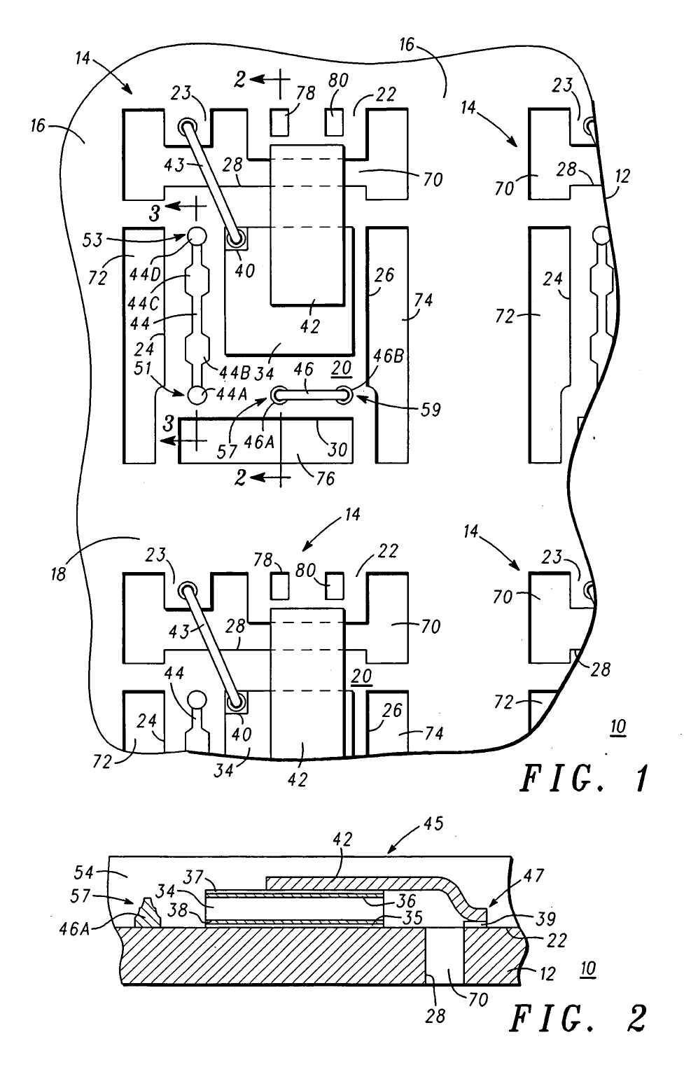

FIG. 1 is a top view of a portion of a support substrate 12 used in the manufacture of a semiconductor component 10 in accordance with an embodiment of the present invention. By way of example, support substrate 12 is a conductive substrate such as a leadframe having a plurality of component regions 14 coupled to each other via vertically and horizontally oriented tie-bars 16 and 18, respectively. Each component region 14 includes a flag or chip attach region 20 and leads or pad portions 22 and 23. In accordance with one embodiment, flag 20 is a quadrilaterally shaped structure having substantially parallel sides 24 and 26 and substantially parallel sides 28 and 30, wherein sides 24 and 26 are substantially perpendicular to sides 28 and 30. The shape of flag 20 is not a limitation of the present invention, i.e., it can have shapes other than quadrilateral. Suitable materials for leadframe 12 include copper, a copper alloy (e.g., TOMAC 4, TAMAC 5, 2ZFROFC, or CDA194), a copper plated iron/nickel alloy (e.g., copper plated Alloy 42), plated aluminum, plated plastic, or the like. Plating materials include, but are not limited to, copper, silver, multi-layer plating materials such as nickel-palladium and gold, or the like. Although substrate 12 has been described as a leadframe, it should be understood this is not a limitation of the present invention. Other suitable materials for support substrate 12 include epoxy-glass composites, FR-4, ceramics, printed circuit boards, and the like.

In accordance with one embodiment, at least one semiconductor chip 34 having a source electrode 36, a drain electrode 38, and a gate electrode 40 is attached to each flag 20 via a die attach material 35. Source and drain electrodes 36 and 38, respectively, of semiconductor chip 34 and die attach material 35 are further illustrated in FIG. 2. Semiconductor chip 34 comprises an active circuit element such as, for example, a power Metal Oxide Semiconductor Field Effect Transistor (MOSFET), a bipolar transistor, an Insulated Gate Bipolar Transistor (IGBT), an Insulated Gate Field Effect Transistor (IGFET), a thyristor, a diode, a sensor, an analog integrated circuit, a digital integrated circuit, or the like. Alternatively, semiconductor chip 34 may comprise a passive circuit element such as a resistor, a capacitor, an inductor, or the like. In accordance with one embodiment, semiconductor chip 34 is a power MOSFET device.

A conductive attachment structure 42 couples semiconductor chip 34 to lead portion 22. Conductive attachment structure 42 is also referred to as a clip or strap. Conductive attachment structure 42 comprises, for example, a rigid copper or a copper alloy and is optionally plated with silver for attachment to leadframe 12 or semiconductor chip 34 using either a solder or a conductive epoxy as the attachment material. A bonding wire 43 couples gate electrode 40 to lead portion 23.

A positionally adaptable locking feature 44 is attached to a portion of flag 20 adjacent side 24 and a positionally adaptable locking feature 46 is attached to a portion of flag 20 adjacent side 30. In accordance with one embodiment, positionally adaptable locking feature 44 is a bonding wire coupled in a stitch bond configuration. This configuration is commonly referred to as a stitch wire bond. By way of example, positionally adaptable locking feature 44 has an end 44A coupled to a region 51 of flag 20 and an opposing end 44D coupled to a region 53 of flag 20. Although positionally adaptable locking feature 44 is shown as being stitched or bonded to support substrate 12 at four locations (identified by reference characters 44A, 44B, 44C, and 44D), it should be understood that this is not a limitation of the present invention. The wire comprising positionally adaptable locking feature 44 can be comprised of a single stitch, two stitches, three stitches or more stitches.

Positionally adaptable locking 46 is attached to a portion of flag 20 adjacent side 30. In accordance with an embodiment of the present invention, positionally adaptable locking 46 is a bonding wire. Positionally adaptable locking feature 46 has an end 46A coupled to a region 57 of flag 20 and an opposing end 46B coupled to a region 59 of flag 20. Suitable materials for positionally adaptable locking features 44 and 46 include gold, aluminum, copper, or the like. Although positionally adaptable locking features 44 and 46 are described as being formed substantially parallel to sides 24 and 30, respectively, this is not a limitation of the present invention. There may be one, two, three, or more bonding wires attached to flag 20 and they may be attached in orientations other than being substantially parallel to the sides of the flag. For example, two bonding wires may be formed on flag 20 such that one is catty-corner to the corner formed by the intersection of sides 24 and 28 and the other is catty-corner to the corner formed by the intersection of sides 26 and 30. Alternatively, a plurality of bonding wires that are parallel to each other may be formed on flag 20. In yet another alternative, one or more of the bonding wires can have one end attached to flag 20 and an opposing end attached to a tie-bar.

In accordance with another embodiment, one or both positionally adaptable locking features 44 and 46 are placed in close proximity to semiconductor chip 34, i.e., within about 254 micrometers (about 10 mils) of semiconductor chip 34. In accordance with another embodiment, one or both positionally adaptable locking features 44 and 46 are within about 25.4 micrometers (1 mil) of semiconductor chip 34. Placing positionally adaptable locking features 44 and 46 in close proximity to semiconductor chip 34 limits migration or movement of semiconductor chip 34 during high temperature processing steps in which die attach material 35 may liquefy and flow out from under semiconductor chip 34. When positionally adaptable locking features 44 and 46 are formed before semiconductor chip 34 is mounted to flag 20, they not only help to limit migration of semiconductor chip 34, they may also serve as alignment aids for locating semiconductor chip 34 on flag 20. Accordingly, positionally adaptable locking features 44 and 46 may serve as alignment aids during subsequent processing steps and are also referred to as adhesion and alignment features. Because the positionally adaptable locking features promote adhesion of encapsulants such as a mold compound to substrate 12 and semiconductor chip 34, they are also referred to as encapsulating adhesion-promotion features. Semiconductor chip 34 may be mounted to flag 20 either before or after formation of positionally adaptable locking features 44 and 46.

It should be understood that regions 70, 72, 74, 76, 78, and 80 are openings that extend through support substrate 12.

FIG. 2 is a cross-sectional side view of a portion of semiconductor component 10 at a later stage of manufacture in accordance with an embodiment of the present invention. What is shown in FIG. 2 is a cross-sectional side view of one of component regions 14 taken along section line 2-2 of FIG. 1 after encapsulation by a mold compound 54 and after singulation into individual semiconductor components 10. FIG. 2 further illustrates source electrode 36 and drain electrode 38 of semiconductor chip 34 and die attach material 35. Source electrode 36 preferably comprises a solderable electrically conductive material such as aluminum, an aluminum alloy, or the like. Drain electrode 38 preferably comprises a solderable electrically conductive material such as, for example, one or more layers of Titanium-Nickel-Silver (TiNiAg), Chromium-Nickel-Gold (CrNiAu), or the like.

Drain electrode 38 is coupled to leadframe 12 through a die attach material 35. Portion 45 of conductive attachment structure 42 is attached to source electrode 36 through an electrically conductive attachment layer 37 and portion 47 of conductive attachment structure 42 is coupled to lead 22. By way of example, portion 45 is coupled to source electrode 36 via a die attach material 37 and portion 47 is coupled to lead portion 22 via a solder attach material 39. Suitable materials for attachment layers 35, 37 and 39 include solder, high conductivity epoxy materials such as CEL9750 HFLO (AL3) epoxy, CEL9210 HFLO (AL2) epoxy (both CEL9000 series epoxies are available from Hitachi Chemical), EMF 760a epoxy (available from Sumitomo Plastics America), or the like. The material for coupling conductive attachment structure 42 to semiconductor chip 34 and lead portion 22 is not a limitation of the present invention.

In addition, FIG. 2 illustrates end 46A of positionally adaptable locking feature 46 coupled to a region 57 of flag 20, side 28, and opening 70.

FIG. 3 is a cross-sectional side view of a portion of semiconductor component 10 taken along section line 3-3 of FIG. 1 at a later stage of manufacture. What is shown in FIG. 3 is a cross-sectional side view of bonding wire 44 coupled to support substrate 12 using stitch bonding after encapsulation by a mold compound 54 and after singulation into individual semiconductor components 10. As those skilled in the art are aware, during stitch bonding, end regions 44A and 44D and central portions 44B and 44C of bonding wire 44 are bonded to support substrate 12. Preferably, end regions 44A and 44D and central regions 44B and 44C are bonded to support substrate 12 using thermocompression bonding techniques. In the process of separating bonding wire 44 from the wirebonding tool, tips or tails 44E and 44F of bonding wire 44 are formed. Tips 44E and 44F extend from support substrate 12 and provide additional surface area to which adhesive encapsulating material can bond.

In accordance with an embodiment in which encapsulating material 54 is a mold compound, leadframe 12 is placed in a mold cavity (not shown) and the mold compound is injected into the mold cavity. Preferably, the mold compound covers the exposed portions of flag 20, leads 22 and 23, the exposed portions of semiconductor chip 34, and positionally adaptable locking features 44 and 46, which locking features 44 and 46 increase the surface area to which mold compound can bond. An advantage of the present invention is that the surface area of positionally adaptable locking features 44 and 46 can be further increased by increasing the diameters of the bonding wires.

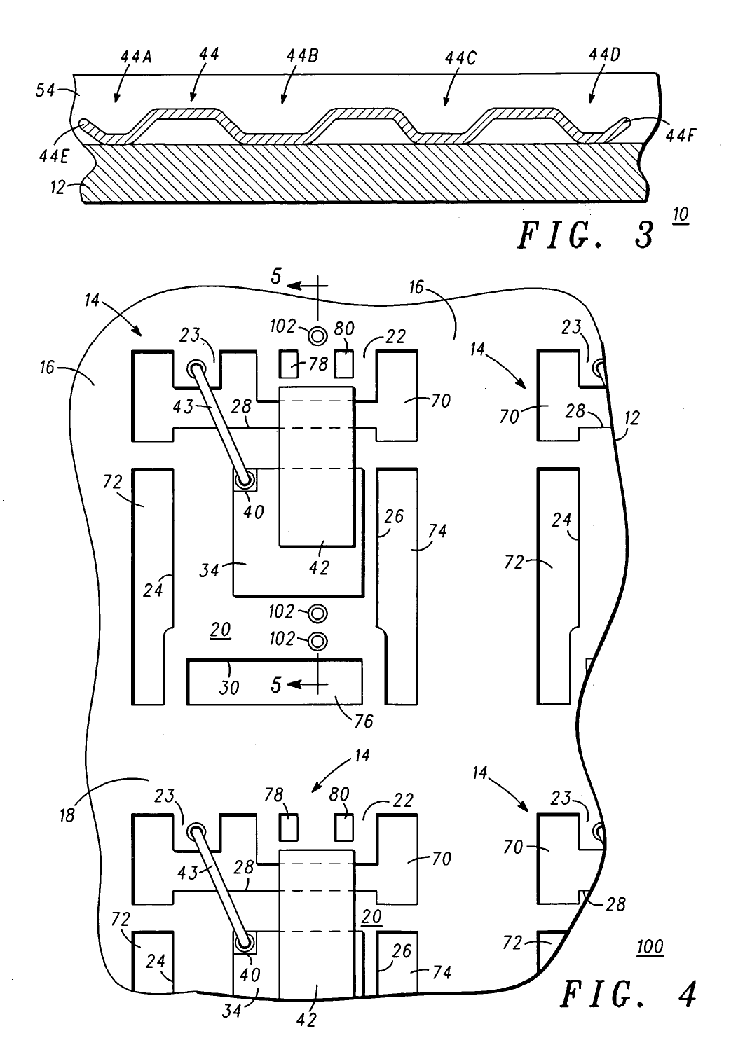

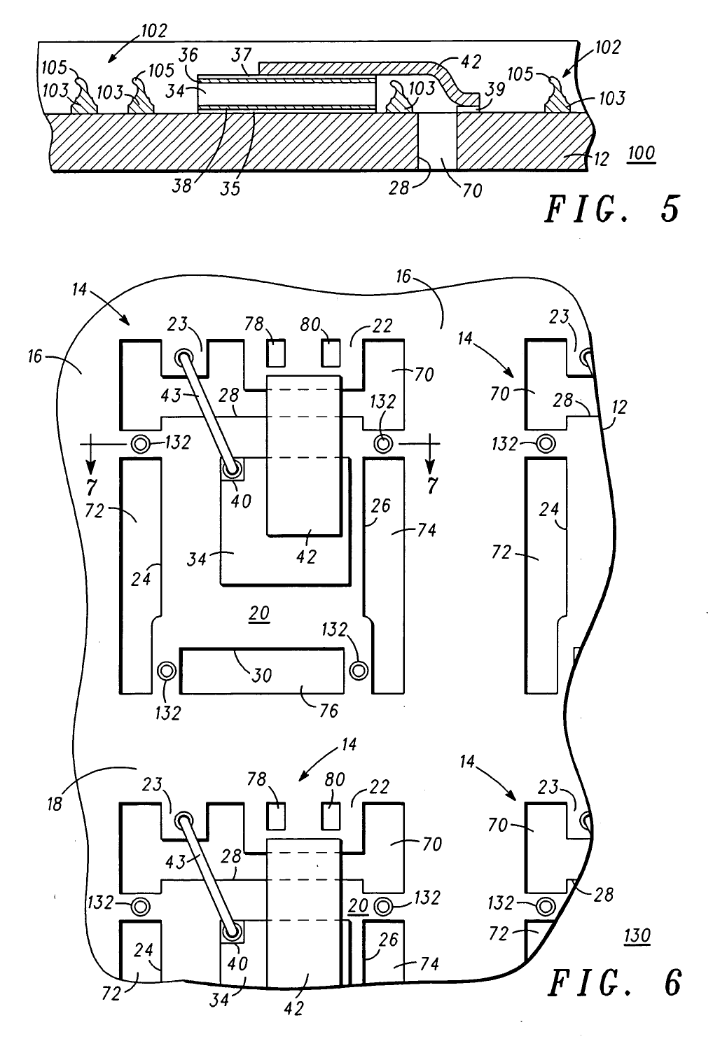

FIG. 4 is a top view of a portion of a support substrate 12 having a plurality of component regions 14 used in the manufacture of a semiconductor component 100 in accordance with an embodiment of the present invention. Semiconductor component 100 is further illustrated in FIG. 5. At the stage of manufacture shown in FIG. 4, semiconductor component 100 includes leadframe 12 having flags 20 and leads 22 and 23, semiconductor chips 34 coupled to flags 20, leads 22 coupled to semiconductor chips 34 by conductive attachment structures 42, and gate electrodes 40 coupled to leads 23 by bonding wires 43.

Preferably, semiconductor component 100 has one or more positionally adaptable locking features 102 that are comprised of the ends or stubs of bonding wires. Positionally adaptable locking features 102 can be formed using a wire bonding tool wherein the bonding wires are broken near the ends of the bonding wires to form wire posts 102. Wire posts 102 are also referred to as posts, stubs, or protrusions. Referring now to FIG. 5 and in accordance with one embodiment, wire posts 102 form protrusions extending from leadframe 12 which protrusions are comprised of a base structure 103 from which a severed wire 105 extends. In accordance with another embodiment, wire posts 102 are comprised of base structure 103, i.e., the bonding wire has been severed at base structure 103 such that a severed wire is not formed. Wire posts 102 increase the surface area to which mold compound 54 can bond. Suitable materials for wire posts 102 include gold, aluminum, copper, or the like.

FIG. 6 is a top view of a portion of a support substrate 12 having a plurality of component regions 14 used in the manufacture of a semiconductor component 130 in accordance with another embodiment of the present invention. Semiconductor component 130 is further illustrated in FIG. 7. At the stage of manufacture shown in FIG. 6, semiconductor component 130 includes leadframe 12 having flags 20, leads 22 and 23, semiconductor chips 34 coupled to flags 20, source electrodes 36 coupled to leads 22 through conductive attachment structures 42, and gate electrodes 40 coupled to leads 23 by bonding wires 43. Semiconductor component 130 includes one or more positionally adaptable locking features comprising wire posts 132 wire bonded to support substrate 12. In accordance with the embodiment of FIGS. 6 and 7, wire posts 132 are formed on the portion of support substrate 12 adjacent to the portions of support substrate 12 that will be sawed during the step of singulation. The number and locations of wire posts 132 are not limitations of the present invention. Like wire posts 102 of FIGS. 4 and 5, wire posts 132 form protrusions extending from leadframe 12 which protrusions are comprised of a base structure 133 from which a severed wire 135 extends. In accordance with another embodiment, wire posts 132 are comprised of base structure 103, i.e., the bonding wire has been severed at base structure 103 such that a severed wire is not formed. Wire posts 132 increase the surface area to which encapsulating material 54 can bond. Suitable materials for wire posts 132 include gold, aluminum, copper, or the like.

FIG. 7 is a cross-sectional side view of a portion of semiconductor component 130 of FIG. 6 at a later stage of manufacture. What is shown in FIG. 7 is a cross-sectional side view of one of component regions 14 taken along section line 7-7 of FIG. 6 after encapsulation by a mold compound 54 and after singulation into individual semiconductor components 130.

Like the embodiment shown in FIG. 5, the embodiment of FIG. 7 includes source electrode 36 coupled to lead 22 (not shown in FIG. 7) by conductive attachment structure 42 and drain electrode 38 of semiconductor chip 34 coupled to flag 20 through adhesive layer 35.

Wire bonds 132 extend from support substrate 12 into encapsulant 54. Like wire posts 102, wire posts 132 increase the surface area to which encapsulant 54 can adhere.

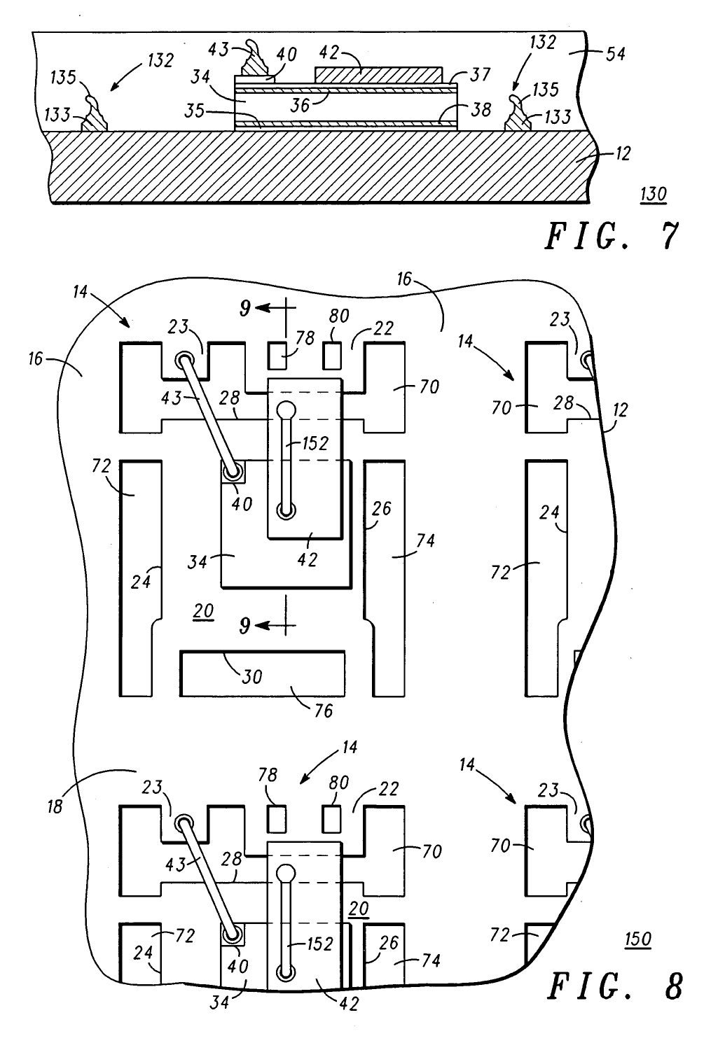

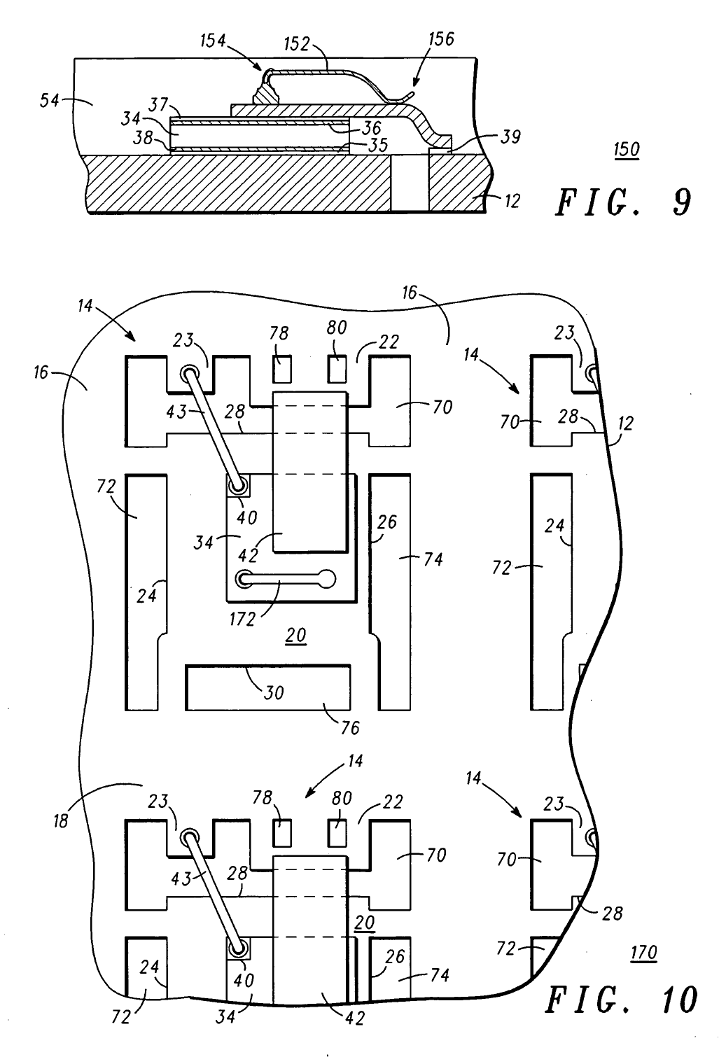

FIG. 8 is a top view of a portion of a support substrate 12 having a plurality of component regions 14 used in the manufacture of a semiconductor component 150 in accordance with another embodiment of the present invention. Semiconductor component 150 is further shown in FIG. 9. At the stage of manufacture shown in. FIG. 8, semiconductor component 150 includes leadframe 12 having flags 20, leads 22 and 23, semiconductor chips 34 coupled to flags 20, source electrodes 36 coupled to leads 22 through conductive attachment structures 42, and gate electrodes 40 coupled to leads 23 by bonding wires 43.

Semiconductor component 150 includes one or more positionally adaptable locking features 152 comprising bonding wires coupled to conductive attachment structure 42. Like bonding wires 44 and 46, bonding wire 152 increases the surface area to which encapsulant material 54 can adhere. Alternatively, positionally adaptable locking feature 152 can be a bonding wire, a wire post, a combination of a bonding wire and a wire bond post, a metallic protrusion, a metal finger, or the like.

FIG. 9 is a cross-sectional side view of a portion of semiconductor component 150 of FIG. 8 at a later stage of manufacture. What is shown in FIG. 9 is a cross-sectional side view of one of component regions 14 taken along section line 9-9 of FIG. 8 after encapsulation by a mold compound 54 and after singulation to form semiconductor component 150. Like the embodiment shown in FIG. 2, the embodiment of FIG. 9 includes source electrode 36 coupled to lead 22 by conductive attachment structure 42 and drain electrode 38 of semiconductor chip 34 coupled to flag 20 through adhesive layer 35.

A bonding wire 152 extends from conductive attachment structure 42 into mold compound 54. Bonding wire 152 has a head end 154 and a tail or tip end 156. Like bonding wires 44 and 46, bonding wire 152 increases the surface area to which encapsulant 54 can adhere.

FIG. 10 is a top view of a portion of a support substrate 12 having a plurality of component regions 14 used in the manufacture of a semiconductor component 170 in accordance with another embodiment of the present invention. At the stage of manufacture shown in FIG. 10, semiconductor component 170 includes leadframe 12 having flags 20, leads 22 and 23, semiconductor chips 34 coupled to flags 20, source electrodes 36 coupled to leads 20 by conductive attachment structures 42, and gate electrodes 40 coupled to leads 23 by bonding wires 43.

Semiconductor component 170 includes one or more positionally adaptable locking features 172 comprising bonding wires bonded to source electrode 36 of semiconductor chip 34. Like bonding wires 44 and 46, bonding wires 172 increase the surface area to which encapsulant 54 can adhere. Alternatively, wiring posts or a combination of bonding wires and wiring posts can be formed on conductive attachment structures 42.

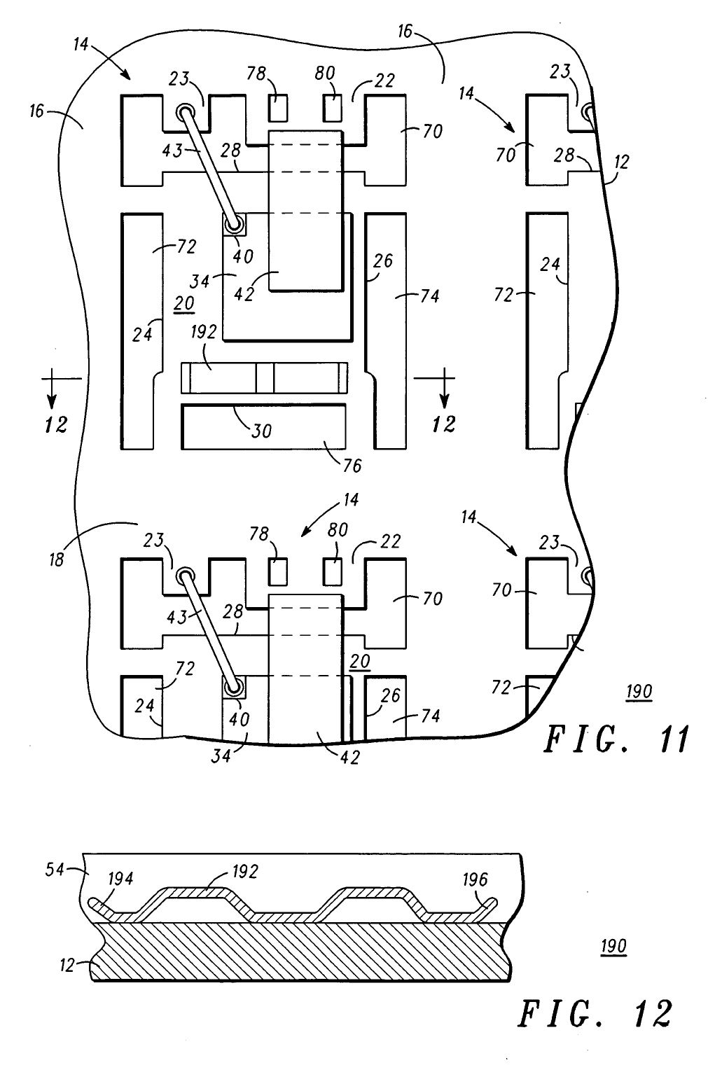

FIG. 11 is a top view of a portion of a support substrate 12 having a plurality of component regions 14 used in the manufacture of a semiconductor component 190 in accordance with another embodiment of the present invention. Semiconductor component 190 is further shown in FIG. 12. At the stage of manufacture shown in FIG. 1, semiconductor component 190 includes leadframe 12 having flags 20, leads 22 and 23, semiconductor chips 34 coupled to flags 20, source electrodes 36 coupled to leads 20 by conductive attachment structures 42, and gate electrodes 40 coupled to leads 23 by bonding wires 43.

Semiconductor component 190 includes one or more positionally adaptable locking features 192 comprising ribbon bonds bonded to source electrode 36 of semiconductor chip 34. Like bonding wires 44 and 46, ribbon bonds 192 increase the surface area to which encapsulant 54 can adhere.

FIG. 12 is a cross-sectional side view of a portion of semiconductor component 190 of FIG. 11 at a later stage of manufacture. What is shown in FIG. 12 is a cross-sectional side view of one of component regions 14 taken along section line 12-12 of FIG. 11 after encapsulation by a mold compound 54 and after singulation to form semiconductor component 190. Like the embodiment shown in FIG. 2, the embodiment of FIG. 12 includes source electrode 36 coupled to lead 22 by conductive attachment structure 42 and drain electrode 38 of semiconductor chip 34 coupled to flag 20 through adhesive layer 35.

Ribbon bonds 192 extend from source electrode 36 into mold compound 54. Ribbon bonds 192 increase the surface area to which encapsulant 54 can adhere.

Although the semiconductor component has been described and shown as a semiconductor chip comprising a discrete semiconductor device, this is not a limitation of the present invention. Alternatively, the semiconductor chip can include an integrated circuit. When the semiconductor chip includes an integrated circuit, dummy bonding pads are preferably formed on the semiconductor chip to allow formation of a metallurgical bond with the bonding wire. The dummy pads are electrically isolated structures and may also be referred to as inert pads or electrically nonfunctional pads.

By now it should be appreciated that a semiconductor component having at least one positionally adaptable feature that serves as a locking and alignment feature and a method for manufacturing the semiconductor component have been provided. In accordance with the present invention, the locking feature comprises a protrusion extending away from the major surface of a support substrate at an angle of less than about 180 degrees. The protrusion may be a bonding wire, a wire bond post, a metallic protrusion, a protrusion comprising material to which mold compound attaches, or the like. An advantage of forming the protrusions using bonding wires or wire bond posts is cost reduction because of the availability of wire bonders and ribbon bonders in semiconductor manufacturing facilities. In addition, the locking features can be used as alignment aids and to decrease the movement or migration of semiconductor chips that may occur when the die attach material liquefies during high temperature processing steps. The use of bonding wires or wire bond posts increases the flexibility of the process when the locking features are not used as alignment aids because it allows forming the locking features after bonding the semiconductor chip to the support substrate.

Locking features in accordance with the present invention also increase the amount of heat that can be transported away from the semiconductor chip. Thus, they improve the thermal performance of the semiconductor components.

Although certain preferred embodiments and methods have been disclosed herein, it will be apparent from the foregoing disclosure to those skilled in the art that variations and modifications of such embodiments and methods may be made without departing from the spirit and scope of the invention. For example, the mold lock feature can be formed from stitch wire bonds or ribbon wire bonds. The locking features can be formed to extend under a portion of the semiconductor chip. One advantage of a portion of the locking feature extending under the semiconductor chip is that it can set a desired standoff height of the semiconductor chip from the surface of the support substrate. It is intended that the invention shall be limited only to the extent required by the appended claims and the rules and principles of applicable law.

What is claimed is:

1. A semiconductor component, comprising:
a substrate having first and second major surfaces;
a semiconductor chip coupled to the first major surface of the substrate;
at least one positionally adaptable locking feature coupled to at least one of the substrate or the semiconductor chip, wherein the primary functionality of the at least one positionally adaptable locking feature is to increase the mechanical integrity of the semiconductor component; and
an encapsulant coupled to the at least one positionally adaptable locking feature.

2. The semiconductor component of claim 1, wherein the substrate comprises a conductive substrate having a flag portion.

3. The semiconductor component of claim 2, wherein the at least one positionally adaptable locking feature comprises a bonding wire.

4. The semiconductor component of claim 3, wherein the bonding wire has a first portion coupled to a first region of the substrate and a second portion coupled to a second region of the substrate.

5. The semiconductor component of claim 3, wherein the bonding wire has a first portion coupled to a first region of the substrate and a second portion coupled to a first region of the semiconductor chip.

6. The semiconductor component of claim 1, wherein the at least one positionally adaptable locking feature comprises one of a bonding wire coupled in a stitch bond configuration or an electrically conductive strip coupled in a ribbon bond configuration.

7. The semiconductor component of claim 1, wherein the at least one positionally adaptable locking feature comprises a wire bond post having a base portion.

8. The semiconductor component of claim 7, wherein the wire bond post further comprises a severed wire extending from the base portion.

9. The semiconductor component of claim 1, wherein the at least one positionally adaptable locking feature comprises a plurality of wire bond posts bonded to the substrate.

10. The semiconductor component of claim 1, wherein the at least one positionally adaptable locking feature comprises:
a first bonding wire having first and second ends, the first end of the first bonding wire coupled to a first region of the substrate and the second end of the first bonding wire coupled to a second region of the substrate; and
a second bonding wire having first and second ends, the second end of the second bonding wire coupled to a third region of the substrate and the second end of the second bonding wire coupled to a fourth region of the substrate.

11. A semiconductor component, comprising:
a conductive substrate having a surface;
a semiconductor chip coupled to the surface;
a locationally flexible locking feature coupled to at least one of the semiconductor chip or the conductive substrate, wherein the primary functionality of the locationally flexible locking feature is to increase the mechanical integrity of the semiconductor component; and
an encapsulating material coupled to the locationally flexible locking feature.

12. The semiconductor component of claim 11, wherein the conductive substrate comprises a leadframe.

13. The semiconductor component of claim 12, wherein the leadframe comprises a flag portion and a lead portion, the semiconductor chip coupled to the flag portion, and further including:
a clip coupled to the semiconductor chip; and
at least one of a bonding wire or a wire bond post coupled to the clip.

14. The semiconductor component of claim 11, wherein the locationally flexible locking feature comprises a protrusion extending from the surface of the conductive substrate.

15. The semiconductor component of claim 14, wherein the protrusion comprises an element selected from the group of elements comprising a bonding wire, a wire bond post, a metal finger, an electrically conductive strip coupled in a ribbon bond configuration, and a bonding wire coupled in a stitch bond configuration.

16. The semiconductor component of claim 11, wherein the conductive substrate comprises a leadframe having a flag portion and a tie-bar portion, wherein the combination mold lock and alignment features comprises at least one bonding wire coupled to the flag portion and the tie-bar portion.

17. A method for packaging a semiconductor chip, comprising:
providing a support substrate having a major surface;
coupling a semiconductor chip to the major surface;
coupling a positionally adaptable locking feature to the support substrate; and
disposing an encapsulant on the positionally adaptable locking feature to form a packaged semiconductor chip, wherein the primary functionality of the positionally adaptable locking feature is to increase the mechanical integrity of the packaged semiconductor chip.

18. The method of claim 17, wherein providing the support substrate includes providing a leadframe having a die receiving area.

19. The method of claim 18, wherein coupling the positionally adaptable locking feature to the support substrate includes using a wire bond tool to form the positionally adaptable locking feature.

20. The method of claim 19, wherein using the wire bond tool to make a locking feature includes making the locking feature as a wire bond, a wire bond post, or a combination of wire bonds and wire bond posts, an electrically conductive strip coupled in a ribbon bond configuration, and a bonding wire coupled in a stitch bond configuration.

21. The method of claim 19, wherein coupling a semiconductor chip to the major surface and coupling the positionally adaptable locking feature to the support substrate includes coupling the semiconductor chip to the major surface before coupling the positionally adaptable locking feature to the support substrate.

22. The method of claim 19, wherein coupling a semiconductor chip to the major surface and coupling the positionally adaptable locking feature to the support substrate includes coupling the semiconductor chip to the major surface after coupling the positionally adaptable locking feature to the support substrate.

23. The method of claim 17, wherein coupling the positionally adaptable locking feature to the support substrate includes directly coupling the positionally adaptable locking feature to the support substrate.
